(19) United States
(12) Patent Application Publication
(10) Pub. No.: US 2015/0381154 A1
(43) Pub. Date: Dec. 31, 2015

(54) FLIP-FLOP CIRCUIT

(71) Applicant: Kabushiki Kaisha Toshiba, Tokyo (JP)

(72) Inventor: Muneaki Maeno, Yokohama Kanagawa (JP)

(21) Appl. No.: 14/641,250

(22) Filed: Mar. 6, 2015

(30) Foreign Application Priority Data
Jun. 30, 2014 (JP) 2014-134781

(51) Int. Cl. H03K 3/3562; H03K 3/012

(52) U.S. Cl. CPC H03K 3/35625; H03K 3/012

(57) ABSTRACT

A flip-flop circuit includes a first clocked inverter that is connected to the data terminal at an input node thereof, and outputs a first signal, which is an inversion of the data signal, in accordance with the third and fourth clock signals. The flip-flop circuit includes a first latching inverter that outputs a second signal, which is an inversion of the first signal, at an output node thereof. The flip-flop circuit includes a transfer gate that passes the second signal therethrough and outputs a third signal at an output node thereof in accordance with the first and second clock signals. The flip-flop circuit includes a second latching inverter that is connected to the output node of the transfer gate at an input node thereof and outputs a fourth signal, which is an inversion of the third signal, at an output node thereof.

### CROSS-REFERENCE TO RELATED APPLICATION

This application is based upon and claims the benefit of priority from the prior Japanese Patent Application No. 2014-134781, filed on Jun. 30, 2014, the entire contents of which are incorporated herein by reference.

### BACKGROUND

1. Field

Embodiments described herein relate generally to a flip-flop circuit.

2. Background Art

A conventional flip-flop circuit comprises an input circuit part, a master latch, a slave latch, an output circuit part, and a clock generating circuit that incorporates two inverters.

In the conventional flip-flop circuit, a data signal must be settled before a clock signal changes. For example, if a high-level data signal is to be read at the rising of the next clock signal, the data signal should be brought into a high level before the setup time of the corresponding cell. If the setup time is long, the flip-flop circuit cannot operate at a high speed since the setup time should be considered in operating the flip-flop circuit. In order to improve (reduce) the setup time, the time required for changing the data signal in response to the rising and the falling of the clock signal in the cell connected to the input of the master latch should be reduced, or the rising and the falling of the clock signal in the cell connected to the input of the master latch should be delayed in response to the change in data signal. In the conventional flip-flop circuit, three or four inverters are included in the clock generating circuit to generate delayed clock signals to be inputted to the master latch in order to reduce the setup time from the instant the data signal is settled to the instant the clock signal is changed. Since a further improvement in the speed of circuit operation has been demanded in recent years, the clock signals in the cell are needed to be delayed further.

Furthermore, in order to reduce the setup time, the size of the transistors in the input circuit part and at the input portion of the master latch should be increased, or the transistors should be connected in parallel with each other so that the data signal are received by the master latch more quickly, in addition to the delaying of the clock signals in the cell input to the input circuit part and the input portion of the master latch.

If the size of the transistors in the input circuit part and at the input portion of the master latch is increased or the transistors are connected in parallel with each other, the gate capacitance of the transistors is increased, which causes a problem of a delay in transmitting data signals.

### BRIEF DESCRIPTION OF THE DRAWINGS

FIG. 1 is a diagram showing an example of a configuration of a flip-flop circuit 100 according to a first embodiment; and

FIG. 2 is a diagram showing an example of a configuration of a flip-flop circuit 200 according to a second embodiment.

### DETAILED DESCRIPTION

A flip-flop circuit according to an embodiment includes a clock terminal to which a reference clock signal is input. The flip-flop circuit includes a data terminal to which a data signal is input. The flip-flop circuit includes an output terminal at which an output signal is output. The flip-flop circuit includes a clock signal generating circuit that is connected to the clock terminal at an input node thereof and outputs a first clock signal, which is obtained by inverting the reference clock signal, a second clock signal, which is obtained by inverting the first clock signal, a third clock signal, which is obtained by inverting the second clock signal, and a fourth clock signal, which is obtained by inverting the third clock signal. The flip-flop circuit includes a first clocked inverter that is connected to the data terminal at an input node thereof, receives the fourth clock signal at a first gate thereof and the third clock signal at a second gate thereof, and outputs a first signal, which is an inversion of the data signal, in accordance with the third and fourth clock signals. The flip-flop circuit includes a first latching inverter that is connected to an output node of the first clocked inverter at an input node thereof and outputs a second signal, which is an inversion of the first signal, at an output node thereof. The flip-flop circuit includes a first pMOS transistor that is connected to a power supply at a source thereof and to the output node of the first latching inverter at a gate thereof. The flip-flop circuit includes a second pMOS transistor that is connected to a drain of the first pMOS transistor at a source thereof and to the input node of the first latching inverter at a drain thereof and receives the third clock signal at a gate thereof. The flip-flop circuit includes a first nMOS transistor that is connected to the drain of the second pMOS transistor at a drain thereof and receives the fourth clock signal at a gate thereof. The flip-flop circuit includes a second nMOS transistor that is connected to a source of the first nMOS transistor at a drain thereof, to a ground at a source thereof and to the output node of the first latching inverter at a gate thereof. The flip-flop circuit includes a transfer gate that is connected to the output node of the first latching inverter at an input node thereof, receives the first clock signal at a third gate thereof and the second clock signal at a fourth gate thereof, and passes the second signal therethrough and outputs a third signal at an output node thereof in accordance with the first and second clock signals. The flip-flop circuit includes a second latching inverter that is connected to the output node of the transfer gate at an input node thereof and outputs a fourth signal, which is an inversion of the third signal, at an output node thereof. The flip-flop circuit includes a third pMOS transistor that is connected to the power supply at a source thereof and to the output node of the second latching inverter at a gate thereof. The flip-flop circuit includes a fourth pMOS transistor that is connected to a drain of the third pMOS transistor at a source thereof and to the input node of the second latching inverter at a drain thereof and receives the fourth clock signal at a gate thereof. The flip-flop circuit includes a third nMOS transistor that is connected to the drain of the fourth pMOS transistor at a drain thereof and receives the third clock signal at a gate thereof. The flip-flop circuit includes a fourth nMOS transistor that is connected to a source of the third nMOS transistor at a drain thereof, to the ground at a source thereof and to the output node of the second latching inverter at a gate thereof. The flip-flop circuit includes an output circuit that outputs the output signal to the output terminal based on the fourth signal.

In the following, embodiments will be described with reference to the drawings.

### First Embodiment

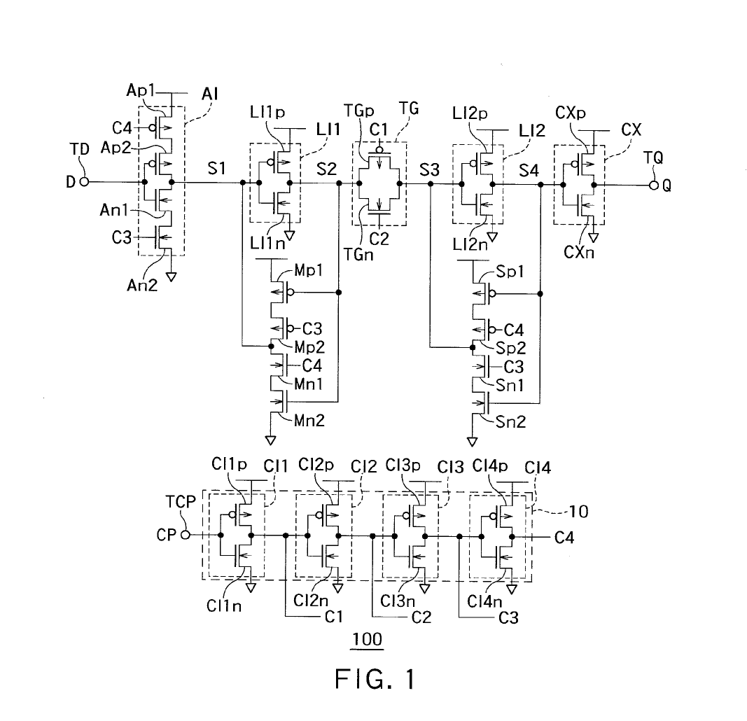

FIG. 1 is a diagram showing an example of a configuration of a flip-flop circuit 100 according to a first embodiment.

As shown in FIG. 1, the flip-flop circuit 100 includes a clock terminal “TCP”, a data terminal “TD”, an output terminal “TQ”, a clock signal generating circuit 10, a first clocked inverter “AI”, a first latching inverter “LI1”, a first pMOS transistor “Mp1”, a second pMOS transistor “Mp2”, a first nMOS transistor “Mn1”, a second nMOS transistor “Mn2”, a transfer gate “TG”, a second latching inverter “LI2”, a third pMOS transistor “Sp1”, a fourth pMOS transistor “Sp2”, a third nMOS transistor “Sn1”, a fourth nMOS transistor “Sn2”, and an output circuit “CX”.

In this example, a first signal “S1” is an inverted signal of a data signal “D”.

A reference clock signal “CP” is input to the clock terminal “TCP”.

The data signal “D” is input to the data terminal “TD”.

An output signal “Q” is output at the output terminal “TQ”.

The clock signal generating circuit 10 is connected to the clock terminal “TCP” at an input node thereof. The clock signal generating circuit 10 outputs a first clock signal “C1”, which is obtained by inverting the reference clock signal “CP”. The clock signal generating circuit 10 also outputs a second clock signal “C2”, which is obtained by inverting the first clock signal “C1”. The clock signal generating circuit 10 also outputs a third clock signal “C3”, which is obtained by inverting the second clock signal “C2”. The clock signal generating circuit 10 also outputs a fourth clock signal “C4”, which is obtained by inverting the third clock signal “C3”.

As shown in FIG. 1, the clock signal generating circuit 10 includes a first clocking inverter “CI1”, a second clocking inverter “CI2”, a third clocking inverter “CI3”, and a fourth clocking inverter “CI4”, for example. An even number of inverters (not shown) may be connected between the second clocking inverter “CI2” and the third clocking inverter “CI3”.

The first clocking inverter “CI1” is connected to the clock terminal “CP” at an input node thereof and outputs the first clock signal “C1”, which is an inverted signal of the reference clock signal “CP”, at an output node thereof.

As shown in FIG. 1, the first clocking inverter “CI1” includes a pMOS transistor “CI1p” and an nMOS transistor “CI1n”, the pMOS transistor “CI1p” is connected to a power supply at a source thereof, to the output node of the first clocking inverter “CI1” at a drain thereof and to the input node of the first clocking inverter “CI1” at a gate thereof, and the nMOS transistor “CI1n” is connected to a ground at a source thereof, to the output node of the first clocking inverter “CI1” at a drain thereof and to the input node of the first clocking inverter “CI1” at a gate thereof, for example.

The second clocking inverter “CI2” is connected to the output node of the first clocking inverter “CI1” at an input node thereof and outputs the second clock signal “C2”, which is an inverted signal of the first clock signal “C1”, at an output node thereof.

As shown in FIG. 1, the second clocking inverter “CI2” includes a pMOS transistor “CI2p” and an nMOS transistor “CI2n”, the pMOS transistor “CI2p” is connected to the power supply at a source thereof, to the output node of the second clocking inverter “CI2” at a drain thereof and to the input node of the second clocking inverter “CI2” at a gate thereof, and the nMOS transistor “CI2n” is connected to the ground at a source thereof, to the output node of the second clocking inverter “CI2” at a drain thereof and to the input node of the second clocking inverter “CI2” at a gate thereof, for example.

The third clocking inverter “CI3” is connected to the output node of the second clocking inverter “CI2” at an input node thereof and outputs the third clock signal “C3”, which is an inverted signal of the second clock signal “C2” (or a clock signal corresponding to the second clock signal “C2”), at an output node thereof. That is, the third clocking inverter “CI3” generates the third clock signal “C3”, which is an inverted signal of the reference clock signal “CP”, based on the second clock signal “C2”.

As shown in FIG. 1, the third clocking inverter “CI3” includes a pMOS transistor “CI3p” and an nMOS transistor “CI3n”, the pMOS transistor “CI3p” is connected to the power supply at a source thereof, to the output node of the third clocking inverter “CI3” at a drain thereof and to the input node of the third clocking inverter “CI3” at a gate thereof, and the nMOS transistor “CI3n” is connected to the ground at a source thereof, to the output node of the third clocking inverter “CI3” at a drain thereof and to the input node of the third clocking inverter “CI3” at a gate thereof, for example.

The third clock signal “C3” lags behind the first clock signal “C1” by delays in the second clocking inverter “CI2” and the third clocking inverter “CI3”.

As described above, an even number of inverters may be connected between the second clocking inverter “CI2” and the third clocking inverter “CI3”. In this case, the third clocking inverter “CI3” outputs the third clock signal “C3”, which is an inverted signal of the second clock signal “C2” (or a clock signal corresponding to the second clock signal “C2”) from the output node thereof.

The fourth clocking inverter “CI4” is connected to the output node of the third clocking inverter “CI3” at an input node thereof and outputs the fourth clock signal “C4”, which is an inverted signal of the third clock signal “C3”, at an output node thereof. That is, the fourth clocking inverter “CI4” generates the fourth clock signal “C4”, which is a non-inverted signal of the reference clock signal “CP”, based on the third clock signal “C3”.

As shown in FIG. 1, the fourth clocking inverter “CI4” includes a pMOS transistor “CI4p” and an nMOS transistor “CI4n”, the pMOS transistor “CI4p” is connected to the power supply at a source thereof, to the output node of the fourth clocking inverter “CI4” at a drain thereof and to the input node of the fourth clocking inverter “CI4” at a gate thereof, and the nMOS transistor “CI4n” is connected to the ground at a source thereof, to the output node of the fourth clocking inverter “CI4” at a drain thereof and to the input node of the fourth clocking inverter “CI4” at a gate thereof, for example.

The fourth clock signal “C4” lags behind the second clock signal “C2” by delays in the third clocking inverter “CI3” and the fourth clocking inverter “CI4”.

The first clocked inverter “AI” is connected to the data terminal “TD” at an input node thereof, receives the fourth clock signal “C4” at a first gate thereof and the third clock signal “C3” at a second gate thereof, and outputs the first signal “S1”, which is an inverted signal of the data signal “D”, in accordance with the third and fourth clock signals “C3” and “C4”.

As shown in FIG. 1, the first clocked inverter “AI” includes a first input pMOS transistor “Ap1”, a second input pMOS transistor “Ap2”, a first input nMOS transistor “An1”, and a second input nMOS transistor “An2”, for example.

The first input pMOS transistor “Ap1” is connected to the power supply at a source thereof and receives the fourth clock signal “C4” at a gate thereof.

The second input pMOS transistor “Ap2” is connected to a drain of the first input pMOS transistor “Ap1” at a source thereof, to the output node of the first clocked inverter “AI” at a drain thereof and to the data terminal “TD” at a gate thereof.

The first input nMOS transistor “An1” is connected to an output node of the first clocked inverter “AI” (or input node of the first latching inverter “LI1”) at a drain thereof, and to the data terminal “TD” at a gate thereof.

The second input nMOS transistor “An2” is connected to a source of the first input nMOS transistor “An1” at a drain thereof and to the ground at a source thereof and receives the third clock signal “C3” at a gate thereof.

A size (plane area) of the first input pMOS transistor “Ap1” is larger than (twice as large as, for example) a size (plane area) of the second input pMOS transistor “Ap2”. In particular, a gate width of the first input pMOS transistor “Ap1” is larger than a gate width of the second input pMOS transistor “Ap2”.

Therefore, a driving capacity of the first input pMOS transistor “Ap1” is higher than (twice as high as, for example) a driving capacity of the second input pMOS transistor “Ap2”.

In addition, a size of the second input nMOS transistor “An2” is larger than (twice as large as, for example) a size of the first input nMOS transistor “An1”. In particular, a gate width of the second input nMOS transistor “An2” is larger than a gate width of the first input nMOS transistor “An1”.

Therefore, a driving capacity of the second input nMOS transistor “An2” is higher than (twice as high as, for example) a driving capacity of the first input nMOS transistor “An1”.

Since the driving capacities of the transistors of the input circuit “AI” are set as described above, transmission of a power supply voltage to the source of the second input pMOS transistor “Ap2” and transmission of a ground voltage to the source of the first input nMOS transistor “An1” are sped up. As a result, the output of the first clocked inverter “AI” can respond to the input thereto more quickly.

Therefore, the data signal “D” is more quickly transmitted to the first latching inverter “LI1”, so that a setup time can be improved without changing an input capacitance.

The first latching inverter “LI1” is connected to the output node of the first clocked inverter “AI” at an input node thereof and outputs the second signal “S2”, which is an inversion of the first signal “S1”.

As shown in FIG. 1, the first latching inverter “LI1” includes a fifth pMOS transistor “LI1p” and a fifth nMOS transistor “LI1n”, for example.

The fifth pMOS transistor “LI1p” is connected to the power supply at a source thereof, to an output node of the first latching inverter “LI1” at a drain thereof and to the input node of the first latching inverter “LI1” at a gate thereof.

The fifth nMOS transistor “LI1n” is connected to the ground at a source thereof, to the output node of the first latching inverter “LI1” at a drain thereof and to the input node of the first latching inverter “LI1” at a gate thereof.

The first pMOS transistor “Mp1” is connected to the power supply at a source thereof and to the output node of the first latching inverter “LI1” at a gate thereof.

The second pMOS transistor “Mp2” is connected to a drain of the first pMOS transistor “Mp1” at a source thereof and to the input node of the first latching inverter “LI1” at a drain thereof and receives the third clock signal “C3” at a gate thereof.

The first nMOS transistor “Mn1” is connected to the drain of the second pMOS transistor “Mp2” at a drain thereof and to the drain of the second nMOS transistor “Mn2” at a source thereof, and receives the fourth clock signal “C4” at a gate thereof.

The second nMOS transistor “Mn2” is connected to a source of the first nMOS transistor “Mn1” at a drain thereof, to the ground at a source thereof and to the output node of the first latching inverter “LI1” at a gate thereof.

The transfer gate “TG” is connected to the output node of the first latching inverter “LI1” at an input node thereof, receives the first clock signal “C1” at a third gate thereof and the second clock signal “C2” at a fourth gate thereof, and passes the second signal “S2” therethrough and outputs the third signal “S3” at an output node thereof in accordance with the first and second clock signals “C1” and “C2”.

The second latching inverter “LI2” is connected to the output node of the transfer gate “TG” at an input node thereof and outputs the fourth signal S4, which is an inversion of the third signal “S3”, at an output node thereof.

As shown in FIG. 1, the second latching inverter “LI2” includes a sixth pMOS transistor “LI2p” and a sixth nMOS transistor “LI2n”, for example.

The sixth pMOS transistor “LI2p” is connected to the power supply at a source thereof, to the output node of the second latching inverter “LI2” at a drain thereof and to the input node of the second latching inverter “LI2” at a gate thereof.

The sixth nMOS transistor “LI2n” is connected to the ground at a source thereof, to the output node of the second latching inverter “LI2” at a drain thereof and to the input node of the second latching inverter “LI2” at a gate thereof.

The third pMOS transistor “Sp1” is connected to the power supply at a source thereof and to the output node of the second latching inverter “LIZ” at a gate thereof.

The fourth pMOS transistor “Sp2” is connected to a drain of the third pMOS transistor “Sp1” at a source thereof and to the input node of the second latching inverter “LI2” at a drain thereof and receives the fourth clock signal “C4” at a gate thereof.

The third nMOS transistor “Sn1” is connected to the drain of the fourth pMOS transistor “Sp2” at a drain thereof and receives the third clock signal “C3” at a gate thereof.

The fourth nMOS transistor “Sn2” is connected to a source of the third nMOS transistor “Sn1” at a drain thereof, to the ground at a source thereof and to the output node of the second latching inverter “LI2” at a gate thereof.

As described above, the third clock signal “C3”, which is an inverted signal of the reference clock signal “CP”, is supplied to three gates of the second input nMOS transistor “An2”, the second pMOS transistor “Mp2” and the third nMOS transistor “Sn1”.

The fourth clock signal “C4”, which is a non-inverted signal of the reference clock signal “CP”, is supplied to three gates of the first input pMOS transistor “Ap1”, the first nMOS transistor “Mn1” and the fourth pMOS transistor “Sp2”.

The output circuit “CX” outputs the output signal “Q” at the output terminal “TQ” based on the fourth signal “S4”. More specifically, the output circuit “CX” outputs the output signal “Q”, which is an inversion of the fourth signal “S4”, to the output terminal “TQ”.

The output circuit “CX” is an output inverter that inverts the input signal and outputs the output signal “Q” to the output terminal “TQ”. As shown in FIG. 1, the output circuit “CX” includes an output pMOS transistor “CXp” and an output nMOS transistor “CXn”, for example.

The output pMOS transistor “CXp” is connected to the power supply at a source thereof, to an output node of the output circuit “CX” at a drain thereof and to an input node of the output circuit “CX” at a gate thereof.

The output nMOS transistor “CXn” is connected to the ground at a source thereof, to the output node of the output circuit “CX” at a drain thereof and to the input node of the output circuit “CX” at a gate thereof.

As shown in FIG. 1, the transfer gate “TG” includes a first switch pMOS transistor “TGp” and a first switch nMOS transistor “TGn”, for example.

The first switch pMOS transistor “TGp” is connected to the input node of the transfer gate “TG” at a source thereof and to the output node of the transfer gate “TG” at a drain thereof and receives the first clock signal “C1” at a gate thereof.

The first switch nMOS transistor “TGn” is connected to the input node of the transfer gate “TG” at a drain thereof and to the output node of the transfer gate “TG” at a source thereof and receives the second clock signal “C2” at a gate thereof.

Next, operational characteristics of the flip-flop circuit 100 configured as described above will be described.

As described above, in the flip-flop circuit 100, the third clock signal “C3”, which is an inverted signal of the reference clock signal “CP”, is supplied to three gates of the second input nMOS transistor “An2”, the second pMOS transistor “Mp2” and the third nMOS transistor “Sn1”.

In addition, in the flip-flop circuit 100, the fourth clock signal “C4”, which is a non-inverted signal of the reference clock signal “CP”, is supplied to three gates of the first input pMOS transistor “Ap1”, the first nMOS transistor “Mn1” and the fourth pMOS transistor “Sp2”.

That is, the non-inverted signals of the reference clock signal are supplied to three gates and the inverted signals are also supplied to three gates in the flip-flop circuit 100 according to this embodiment, while the non-inverted signals of the reference clock signal are supplied to two gates and the inverted signals are also supplied to two gates according to prior art, for example. Therefore, a gate load can be increased by a factor of 3/2=1.5.

Therefore, the gate capacity connected to the outputs of the third clocking inverter “CI3” and the fourth clocking inverter “CI4” in the flip-flop circuit 100 according to this embodiment is increased. As a result, the fourth clock signal “C4”, which is an non-inverted signal of the reference clock signal “CP”, and the third clock signal “C3”, which is an inverted signal of the reference clock signal “CP” can be delayed.

That is, the flip-flop circuit 100 can delay the clock signal with respect to the data signal “D” and therefore can reduce the setup time from the instant the data signal is settled to the instant to the clock signal changes.

In addition, as described above, the first clock signal “C1”, which is an inverted signal of the reference clock signal “CP”, is supplied only to one gate of the first switch pMOS transistor “TGp”. In addition, the second clock signal “C2”, which is a non-inverted signal of the reference lock signal “CP”, is supplied only to one gate of the first switch nMOS transistor “TGn”.

This reduces the gate load connected to the outputs of the first clocking inverter “CI1” and the second clocking inverter “CI2”. Therefore, transmission of the first clock signal “C1” and the second clock signal. “C2” can be sped up. That is, the time from a change of the reference clock signal “CP” to a change of the output signal “Q” can be reduced.

In addition, as described above, the driving capacity of the first input pMOS transistor “Ap1” is preferably set to be higher than the driving capacity of the second input pMOS transistor “Ap2” and the driving capacity of the second input nMOS transistor “An2” is preferably set to be higher than the driving capacity of the first input nMOS transistor “An1”.

Since the driving capacities of the transistors in the input circuit “AI” are set as described above, transmission of the power supply voltage to the source of the second input pMOS transistor “Ap2” and transmission of the ground voltage to the source of the first input nMOS transistor “An1” are sped up. As a result, the output of the first clocked inverter “AI” can respond to the input thereto more quickly.

Therefore, the data signal “D” is more quickly transmitted to the first latching inverter “LI1”, so that the setup can be improved without changing the input capacitance.

As described above, the flip-flop circuit according to the first embodiment can improve the setup.

### Second Embodiment

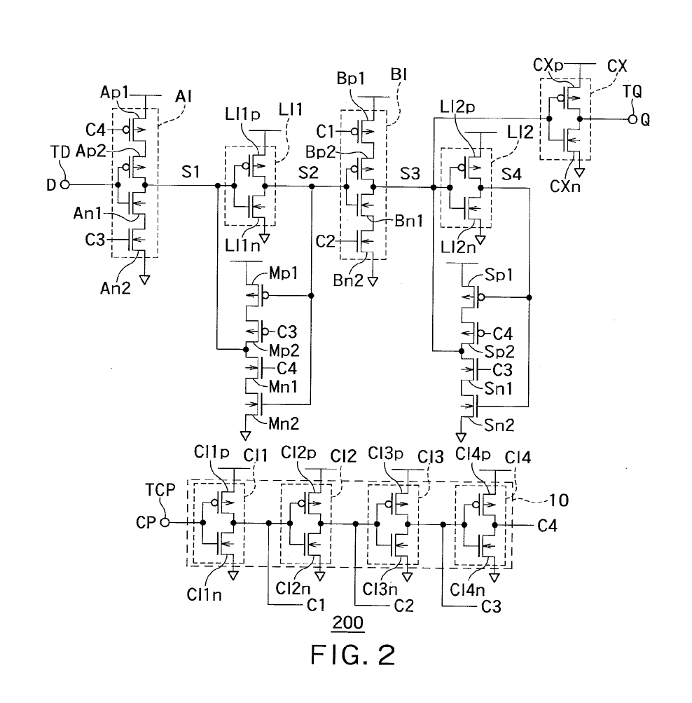

FIG. 2 is a diagram showing an example of a configuration of a flip-flop circuit 200 according to a second embodiment. In FIG. 2, the same reference symbols as those in FIG. 1 denote the same components as those in the first embodiment.

As shown in FIG. 2, the flip-flop circuit 200 includes the clock terminal “TCP”, the data terminal “TD”, the output terminal “TQ”, the clock signal generating circuit 10, the first clocked inverter “AI”, the first latching inverter “LI1”, the first pMOS transistor “Mp1”, the second pMOS transistor “Mp2”, the first nMOS transistor “Mn1”, the second nMOS transistor “Mn2”, a second clocked inverter “BI”, the second latching inverter “LI2”, the third pMOS transistor “Sp1”, the fourth pMOS transistor “Sp2”, the third nMOS transistor “Sn1”, the fourth nMOS transistor “Sn2”, and the output circuit “CX”.

In short, the flip-flop circuit 200 according to the second embodiment shown in FIG. 2 differs from the flip-flop circuit 100 shown in FIG. 1 in that the flip-flop circuit 200 includes the second clocked inverter “BI” instead of the transfer gate “TG”.

The second clocked inverter “BI” is connected to the output node of the first latching inverter “LI1” at an input node thereof and to the input node of the second latching inverter “LI2” at an output node thereof, receives the first clock signal “C1” at a third gate thereof and the second clock signal “C2” at a fourth gate thereof, and inverts the second signal “S2” and outputs the third signal “S3” in accordance with the first and second clock signals “C1” and “C2”.

As shown in FIG. 2, the second clocked inverter “BI” includes a first switch pMOS transistor “Bp1”, a second switch pMOS transistor “Bp2”, a first switch nMOS transistor “Bn1” and a second switch nMOS transistor “Bn2”, for example.

The first switch pMOS transistor “Bp1” is connected to the power supply at a source thereof, and a gate of the first switch pMOS transistor “Bp1” constitutes the third gate of the second clocked inverter “BI”.

The second switch pMOS transistor “Bp2” is connected to a drain of the first switch pMOS transistor “Bp1” at a source thereof, to the output node of the second clocked inverter “BI” at a drain thereof and to the input node of the second clocked inverter “BI” at a gate thereof.

The first switch nMOS transistor “Bn1” is connected to the input node of the second latching inverter “LI2” at a drain thereof and to the input node of the second clocked inverter “BI” at a gate thereof.

The second switch nMOS transistor “Bn2” is connected to a source of the first switch nMOS transistor “Bn1” at a drain thereof and to the ground at a source thereof, and a gate of the second switch nMOS transistor “Bn2” constitutes the fourth gate of the second clocked inverter “BI”.

In this embodiment, the output circuit “CX” outputs the output signal “Q” to the output terminal “TQ” based on the third signal “S3”. That is, the output circuit “CX” outputs the output signal “Q”, which is an inversion of the third signal “S3”, to the output terminal “TQ”.

Since the connections involving the output circuit “CX” are set as described above, signal inversion occurs in the second clocked inverter “BI”. Except that, however, the flip-flop circuit 200 can operate in the same way as the flip-flop circuit 100 according to the second embodiment.

With the flip-flop circuit 100 according to the first embodiment, a waveform of a signal being transmitted is distorted because on-resistances of the transistors occur when the signal passes through the transfer gate “TG”. To the contrary, the flip-flop circuit 200 according to the second embodiment can reduce such a waveform distortion by replacing the transfer gate “TG” with the second clocked inverter “BI”. Therefore, the time from a change of the clock signal to a change of the output can be improved.

The remainder of the configuration and operational characteristics of the flip-flop circuit 200 is the same as that of the flip-flop circuit 100 according to the first embodiment shown in FIG. 1.

That is, the flip-flop circuit according to the second embodiment can improve the setup, as with the flip-flop circuit according to the first embodiment.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A flip-flop circuit, comprising:
a clock terminal to which a reference clock signal is input;
a data terminal to which a data signal is input;
an output terminal at which an output signal is output;
a clock signal generating circuit that is connected to the clock terminal at an input node thereof and outputs a first clock signal, which is obtained by inverting the reference clock signal, a second clock signal, which is obtained by inverting the first clock signal, a third clock signal, which is obtained by inverting the second clock signal, and a fourth clock signal, which is obtained by inverting the third clock signal;
a first clocked inverter that is connected to the data terminal at an input node thereof, receives the fourth clock signal at a first gate thereof and the third clock signal at a second gate thereof, and outputs a first signal, which is an inversion of the data signal, in accordance with the third and fourth clock signals;
a first latching inverter that is connected to an output node of the first clocked inverter at an input node thereof and outputs a second signal, which is an inversion of the first signal, at an output node thereof;
a first pMOS transistor that is connected to a power supply at a source thereof and to the output node of the first latching inverter at a gate thereof;
a second pMOS transistor that is connected to a drain of the first pMOS transistor at a source thereof and to the input node of the first latching inverter at a drain thereof and receives the third clock signal at a gate thereof;
a first nMOS transistor that is connected to the drain of the second pMOS transistor at a drain thereof and receives the fourth clock signal at a gate thereof;
a second nMOS transistor that is connected to a source of the first nMOS transistor at a drain thereof, to a ground at a source thereof and to the output node of the first latching inverter at a gate thereof;
a transfer gate that is connected to the output node of the first latching inverter at an input node thereof, receives the first clock signal at a third gate thereof and the second clock signal at a fourth gate thereof, and passes the second signal therethrough and outputs a third signal at an output node thereof in accordance with the first and second clock signals;
a second latching inverter that is connected to the output node of the transfer gate at an input node thereof and outputs a fourth signal, which is an inversion of the third signal, at an output node thereof;
a third pMOS transistor that is connected to the power supply at a source thereof and to the output node of the second latching inverter at a gate thereof;
a fourth pMOS transistor that is connected to a drain of the third pMOS transistor at a source thereof and to the input node of the second latching inverter at a drain thereof and receives the fourth clock signal at a gate thereof;
a third nMOS transistor that is connected to the drain of the fourth pMOS transistor at a drain thereof and receives the third clock signal at a gate thereof;
a fourth nMOS transistor that is connected to a source of the third nMOS transistor at a drain thereof, to the ground at a source thereof and to the output node of the second latching inverter at a gate thereof; and
an output circuit that outputs the output signal to the output terminal based on the fourth signal.

2. The flip-flop circuit according to claim 1, wherein the clock signal generating circuit comprises:
a first clocking inverter that is connected to the clock terminal at an input node thereof and outputs the first clock signal, which is an inversion of the reference clock signal, at an output node thereof;
a second clocking inverter that is connected to the output node of the first clocking inverter at an input node thereof and outputs the second clock signal, which is an inversion of the first clock signal, at an output node thereof;
a third clocking inverter outputs the third clock signal, which is an inversion of a clock signal corresponding to the second clock signal, at an output node thereof; and
a fourth clocking inverter that is connected to the output node of the third clocking inverter at an input node thereof and outputs the fourth clock signal, which is an inversion of the third clock signal, at an output node thereof.

3. The flip-flop circuit according to claim 2, wherein the clock signal corresponding to the second clock signal is the second clock signal or a clock signal outputted from an even number of inverters to which the second clock signal is inputted.

4. The flip-flop circuit according to claim 1, wherein the first clocked inverter comprises:
a first input pMOS transistor that is connected to the power supply at a source thereof, a gate of the first input pMOS transistor constituting the first gate of the first clocked inverter;
a second input pMOS transistor that is connected to a drain of the first input pMOS transistor at a source thereof, and to the output node of the first clocked inverter at a drain thereof and to the data terminal at a gate thereof;
a first input nMOS transistor that is connected to the input node of the first latching inverter at a drain thereof and to the data terminal at a gate thereof; and
a second input nMOS transistor that is connected to a source of the first input nMOS transistor at a drain thereof and to the ground at a source thereof, a gate of the second input nMOS transistor constituting the second gate of the first clocked inverter.

5. The flip-flop circuit according to claim 2, wherein the first clocked inverter comprises:
a first input pMOS transistor that is connected to the power supply at a source thereof, a gate of the first input pMOS transistor constituting the first gate of the first clocked inverter;
a second input pMOS transistor that is connected to a drain of the first input pMOS transistor at a source thereof, and to the output node of the first clocked inverter at a drain thereof and to the data terminal at a gate thereof;
a first input nMOS transistor that is connected to the input node of the first latching inverter at a drain thereof and to the data terminal at a gate thereof; and
a second input nMOS transistor that is connected to a source of the first input nMOS transistor at a drain thereof and to the ground at a source thereof, a gate of the second input nMOS transistor constituting the second gate of the first clocked inverter.

6. The flip-flop circuit according to claim 4, wherein a driving capacity of the first input pMOS transistor is higher than a driving capacity of the second input pMOS transistor, and a driving capacity of the second input nMOS transistor is higher than a driving capacity of the first input nMOS transistor.

7. The flip-flop circuit according to claim 6, wherein a gate width of the first input pMOS transistor is larger than a gate width of the second input pMOS transistor, and
a gate width of the second input nMOS transistor is larger than a gate width of the first input nMOS transistor.

8. The flip-flop circuit according to claim 5, wherein a driving capacity of the first input pMOS transistor is higher than a driving capacity of the second input pMOS transistor, and
a driving capacity of the second input nMOS transistor is higher than a driving capacity of the first input nMOS transistor.

9. The flip-flop circuit according to claim 8, wherein a gate width of the first input pMOS transistor is larger than a gate width of the second input pMOS transistor, and
a gate width of the second input nMOS transistor is larger than a gate width of the first input nMOS transistor.

10. The flip-flop circuit according to claim 1, wherein the transfer gate comprises:
a first switch pMOS transistor that is connected to the input node of the transfer gate at a source thereof and to the output node of the transfer gate at a drain thereof and receives the first clock signal at a gate thereof; and
a first switch nMOS transistor that is connected to the input node of the transfer gate at a drain thereof and to the output node of the transfer gate at a source thereof and receives the second clock signal at a gate thereof.

11. The flip-flop circuit according to claim 1, wherein the output circuit is an output inverter that inverts an input signal and outputs the output signal to the output terminal.

12. A flip-flop circuit, comprising:
a clock terminal to which a reference clock signal is input;
a data terminal to which a data signal is input;
an output terminal at which an output signal is output;
a clock signal generating circuit that is connected to the clock terminal at an input node thereof and outputs a first clock signal, which is obtained by inverting the reference clock signal, a second clock signal, which is obtained by inverting the first clock signal, a third clock signal, which is obtained by inverting the second clock signal, and a fourth clock signal, which is obtained by inverting the third clock signal;
a first clocked inverter that is connected to the data terminal at an input node thereof, receives the fourth clock signal at a first gate thereof and the third clock signal at a second gate thereof, and outputs a first signal, which is an inversion of the data signal, in accordance with the third and fourth clock signals;
a first latching inverter that is connected to an output node of the first clocked inverter at an input node thereof and outputs a second signal, which is an inversion of the first signal, at an output node thereof;
a first pMOS transistor that is connected to a power supply at a source thereof and to the output node of the first latching inverter at a gate thereof;
a second pMOS transistor that is connected to a drain of the first pMOS transistor at a source thereof and to the input node of the first latching inverter at a drain thereof and receives the third clock signal at a gate thereof;
a first nMOS transistor that is connected to the drain of the second pMOS transistor at a drain thereof and receives the fourth clock signal at a gate thereof;
a second nMOS transistor that is connected to a source of the first nMOS transistor at a drain thereof, to a ground at a source thereof and to the output node of the first latching inverter at a gate thereof;
a second clocked inverter that is connected to the output node of the first latching inverter at an input node thereof, receives the first clock signal at a third gate thereof and the second clock signal at a fourth gate thereof, and inverts the second signal and outputs a third signal in accordance with the first and second clock signals;
a second latching inverter that is connected to the output node of the second clocked inverter at an input node thereof and outputs a fourth signal, which is an inversion of the third signal, at an output node thereof;
a third pMOS transistor that is connected to the power supply at a source thereof and to the output node of the second latching inverter at a gate thereof;
a fourth pMOS transistor that is connected to a drain of the third pMOS transistor at a source thereof and to the input node of the second latching inverter at a drain thereof and receives the fourth clock signal at a gate thereof;
a third nMOS transistor that is connected to the drain of the fourth pMOS transistor at a drain thereof and receives the third clock signal at a gate thereof;
a fourth nMOS transistor that is connected to a source of the third nMOS transistor at a drain thereof, to the ground at a source thereof and to the output node of the second latching inverter at a gate thereof; and
an output circuit that outputs the output signal to the output terminal based on the third signal.

13. The flip-flop circuit according to claim 12, wherein the first clocked inverter comprises:
a first input pMOS transistor that is connected to the power supply at a source thereof, a gate of the first input pMOS transistor constituting the first gate of the first clocked inverter;
a second input pMOS transistor that is connected to a drain of the first input pMOS transistor at a source thereof, and to the output node of the first clocked inverter at a drain thereof and to the data terminal at a gate thereof;
a first input nMOS transistor that is connected to the input node of the first latching inverter at a drain thereof and to the data terminal at a gate thereof; and
a second input nMOS transistor that is connected to a source of the first input nMOS transistor at a drain thereof and to the ground at a source thereof, a gate of the second input nMOS transistor constituting the second gate of the first clocked inverter.

14. The flip-flop circuit according to claim 13, wherein a driving capacity of the first input pMOS transistor is higher than a driving capacity of the second input pMOS transistor, and
a driving capacity of the second input nMOS transistor is higher than a driving capacity of the first input nMOS transistor.

15. The flip-flop circuit according to claim 14, wherein a gate width of the first input pMOS transistor is larger than a gate width of the second input pMOS transistor, and
a gate width of the second input nMOS transistor is larger than a gate width of the first input nMOS transistor.

16. The flip-flop circuit according to claim 12, wherein the output circuit is an output inverter that inverts an input signal and outputs the output signal to the output terminal.
